(19) United States
(12) Patent Application Publication
(10) Pub. No.: US 2025/0383406 A1
(43) Pub. Date: Dec. 18, 2025

(54) APPARATUS AND METHOD FOR CONTROLLING A BATTERY

(71) Applicants: HYUNDAI MOTOR COMPANY, Seoul (KR); KIA CORPORATION, Seoul (KR); THE INDUSTRY & ACADEMIC COOPERATION IN CHUNGNAM NATIONAL UNIVERSITY (IAC), Daejeon (KR)

(72) Inventors: Bo Hyun Lee, Hwaseong-si (KR); Sang Jin Lee, Hwaseong-si (KR); Hyo Kyung Lee, Hwaseong-si (KR); Jong Hoon Kim, Daejeon (KR); Eun Jin Gang, Daejeon (KR); Min Hyeok Kim, Daejeon (KR)

(73) Assignees: HYUNDAI MOTOR COMPANY, Seoul (KR); KIA CORPORATION, Seoul (KR); THE INDUSTRY & ACADEMIC COOPERATION IN CHUNGNAM NATIONAL UNIVERSITY (IAC), Daejeon (KR)

(21) Appl. No.: 18/971,276

(22) Filed: Dec. 6, 2024

(30) Foreign Application Priority Data
Jun. 14, 2024 (KR) 10-2024-0077738

(51) Int. Cl. G01R 31/3842; G01R 31/367

(52) U.S. Cl. CPC G01R 31/3842; G01R 31/367

(57) ABSTRACT

A battery control apparatus and a method are disclosed. A processor of the battery control apparatus may identify average open-circuit voltage (OCV) corresponding to all of a plurality of state-of-charge (SOC) sections by performing at least one of charging a battery, discharging the battery, or any combination thereof by using a designated current smaller than or equal to a threshold current. The processor may obtain a hysteresis parameter according to each of the plurality of SOC sections of the battery by using at least one of the battery information, the average OCV, or any combination thereof. The processor may identify the SOC of the battery while performing at least one of charging the battery, discharging the battery, or any combination thereof, by using the hysteresis parameter and a Kalman filter according to each of the plurality of SOC sections.

### CROSS-REFERENCE TO RELATED APPLICATION

This application claims the benefit of priority to Korean Patent Application No. 10-2024-0077738, filed in the Korean Intellectual Property Office on Jun. 14, 2024, the entire contents of which are incorporated herein by reference.

### TECHNICAL FIELD

The present disclosure relates to a battery control apparatus and method, and more particularly, relates to a technology for identifying a state-of-charge (SOC) of a battery.

### BACKGROUND

According to the net-zero carbon policy, eco-friendly application industries are becoming increasingly important. In particular, electric vehicle (EV) industries are growing significantly as an alternative way of transportation to reduce greenhouse gas emissions that are the major problem of environmental pollution.

Lithium-iron phosphate (LFP) batteries may include characteristics of high output, high energy density, and relatively long lifespan. The LFP batteries may include higher safety than nickel, cobalt, manganese (Ni, Co, Mn) (NCM)-series batteries. The LFP batteries may include flat voltage characteristics because a voltage change amount is very small in a specific SOC section or state (e.g., 20% to 80%).

Moreover, the LFP batteries exhibit hysteresis characteristics, where open-circuit voltage (OCV) is dependent on a previous charge/discharge history and is changed depending on charging and discharging. Studies are needed to accurately estimate SOC based on OCV characteristics caused by these hysteresis characteristics and voltage characteristics.

### SUMMARY

The present disclosure was made to solve the above-mentioned problems occurring in the prior art while advantages achieved by the prior art are maintained intact.

An aspect of the present disclosure provides a battery control apparatus for obtaining a hysteresis parameter for each of a plurality of SOC sections. Another aspect of the present disclosure provides a method thereof.

An aspect of the present disclosure provides a battery control apparatus for applying an extended Kalman filter with different noise parameters for each of the SOC sections Another aspect of the present disclosure provides a method thereof.

An aspect of the present disclosure provides a battery control apparatus for identifying the SOC of a battery by using the hysteresis parameter and the extended Kalman filter. Another aspect of the present disclosure provides a method thereof.

The technical problems to be solved by the present disclosure are not limited to the aforementioned problems. Any other technical problems not mentioned herein should be clearly understood from the following description by those of ordinary skill in the art to which the present disclosure pertains.

According to an aspect of the present disclosure, a battery control apparatus may include a battery, a processor, and a memory. The processor may be configured to identify average open-circuit voltage (OCV) corresponding to all of a plurality of state-of-charge (SOC) sections or state ranges by performing at least one of charging the battery or discharging the battery, or any combination thereof, by using a designated current smaller than or equal to a threshold current. The processor may also be configured to obtain a hysteresis parameter according to each of the plurality of SOC sections or states range of the battery by using at least one of the battery information or the average OCV, or any combination thereof. The processor may also be configured to identify the SOC of the battery while performing at least one of charging the battery or discharging the battery, or any combination thereof, by using the hysteresis parameter and a Kalman filter according to each of the plurality of SOC sections.

In an embodiment, the hysteresis parameter may indicate a ratio between OCVs respectively corresponding to the plurality of SOC sections, which are obtained while performing at least one of the average OCV, charging the battery, or discharging the battery, or any combination thereof.

In an embodiment, the processor may be further configured to identify an OCV corresponding to each of the plurality of sections SOC using the average OCV corresponding to all of the plurality of SOC sections and the hysteresis parameter according to each of the plurality of SOC sections.

In an embodiment, the processor may be further configured to obtain an equivalent model of the battery based on at least one of the OCV corresponding to each of the plurality of SOC sections or the battery information, or any combination thereof, and to obtain the hysteresis parameter corresponding to each of the plurality of SOC sections by using the equivalent model.

In an embodiment, the processor may be configured to obtain the hysteresis parameter corresponding to each of the plurality of SOC sections by performing at least one of charging the battery or discharging the battery, or any combination thereof by using the designated current in each of the plurality of SOC sections.

In an embodiment, the processor may be configured to obtain the hysteresis parameter corresponding to each of the plurality of SOC sections by using a SOC change amount of the battery in each of the plurality of SOC sections.

In an embodiment, the processor may be configured to identify a first hysteresis parameter corresponding to a first SOC section among the plurality of SOC sections, to identify a first OCV corresponding to the first SOC section by using the first hysteresis parameter and the average OCV corresponding to all of the plurality of SOC sections, and to identify the SOC of the battery by applying a first Kalman filter associated with a current integration method to the first OCV.

In an embodiment, the processor may be configured to classify the plurality of SOC sections into the first SOC section and a second SOC section based on voltage characteristics of the battery, and to identify the SOC of the battery by applying a second Kalman filter associated with a measurement equation to second OCV corresponding to the second SOC section.

In an embodiment, a voltage change rate of the first SOC section is lower than a voltage change rate of the second SOC section.

In an embodiment, the processor may be configured to obtain another hysteresis parameter associated with another SOC, which is to be identified after the SOC of the battery is identified, by using the hysteresis parameter corresponding to each of the plurality of SOC sections and an SOC change amount of the battery corresponding to each of the plurality of SOC sections after identifying the SOC of the battery.

According to an aspect of the present disclosure, a battery control method may include identifying an average OCV corresponding to all of a plurality of SOC sections by performing at least one of charging the battery or discharging the battery, or any combination thereof, by using a designated current smaller than or equal to a threshold current. The method may also include obtaining a hysteresis parameter according to each of the plurality of SOC sections of the battery by using at least one of the battery information or the average OCV, or any combination thereof. The method may also include identifying the SOC of the battery while performing at least one of charging the battery or discharging the battery, or any combination thereof, by using the hysteresis parameter and a Kalman filter according to each of the plurality of SOC sections.

In an embodiment, the hysteresis parameter may indicate a ratio between OCVs respectively corresponding to the plurality of SOC sections, which are obtained while performing at least one of the average OCV, charging the battery, or discharging the battery, or any combination thereof.

In an embodiment, identifying the average OCV may further include identifying an OCV corresponding to each of the plurality of SOC sections by using the average OCV corresponding to all of the plurality of SOC sections and the hysteresis parameter according to each of the plurality of SOC sections.

In an embodiment, obtaining the hysteresis parameter according to each of the plurality of SOC sections may further include obtaining an equivalent model of the battery based on at least one of the OCV corresponding to each of the plurality of SOC sections or the battery information, or any combination thereof, and obtaining the hysteresis parameter corresponding to each of the plurality of SOC sections by using the equivalent model.

In an embodiment, obtaining the hysteresis parameter according to each of the plurality of SOC sections may include obtaining the hysteresis parameter corresponding to each of the plurality of SOC sections by performing at least one of charging the battery or discharging the battery, or any combination thereof, by using the designated current in each of the plurality of SOC sections.

In an embodiment, obtaining the hysteresis parameter according to each of the plurality of SOC sections may include obtaining the hysteresis parameter corresponding to each of the plurality of SOC sections by using an SOC change amount of the battery in each of the plurality of SOC sections.

In an embodiment, identifying the SOC of the battery may include identifying a first hysteresis parameter corresponding to a first SOC section among the plurality of SOC sections, identifying a first OCV corresponding to the first SOC section by using the first hysteresis parameter and the average OCV corresponding to all of the plurality of SOC sections, and identifying the SOC of the battery by applying a first Kalman filter associated with a current integration method to the first OCV.

In an embodiment, identifying the SOC of the battery may further include classifying the plurality of SOC sections into the first SOC section and a second SOC section based on voltage characteristics of the battery and identifying the SOC of the battery by applying a second Kalman filter associated with a measurement equation to second OCV corresponding to the second SOC section.

In an embodiment, a voltage change rate of the first SOC section is lower than a voltage change rate of the second SOC section.

In an embodiment, the battery control method may further include obtaining another hysteresis parameter associated with another SOC, which is to be identified after the SOC of the battery is identified, by using the hysteresis parameter corresponding to each of the plurality of SOC sections and an SOC change amount of the battery corresponding to each of the plurality of SOC sections after identifying the SOC of the battery.

### BRIEF DESCRIPTION OF THE DRAWINGS

The above and other objects, features, and advantages of the present disclosure should be more apparent from the following detailed description taken in conjunction with the accompanying drawings, in which:

FIG. 1 shows an example of a block diagram associated with a battery control apparatus, according to an embodiment of the present disclosure;

FIG. 2 shows an example of a flowchart illustrating an operation of a battery control apparatus, according to an embodiment of the present disclosure;

FIG. 3 shows an example of a graph illustrating a battery current and a battery voltage, which are obtained by a battery control apparatus, according to an embodiment of the present disclosure;

FIG. 4 shows an example of a graph illustrating a relationship between open-circuit voltage (OCV) and state-of-charge (SOC) obtained by a battery control apparatus, according to an embodiment of the present disclosure;

FIG. 5 shows an example of a block diagram for describing an operation in which a battery control apparatus obtains an equivalent model of a battery, according to an embodiment of the present disclosure;

FIG. 6 shows an example of a flowchart illustrating an operation of a battery control apparatus, according to an embodiment of the present disclosure;

FIG. 7 shows an example of a graph illustrating the relationship between OCV and SOC corresponding to each of a plurality of SOC sections obtained by a battery control apparatus, according to an embodiment of the present disclosure;

FIG. 8 shows an example of a graph illustrating the relationship between OCV and SOC obtained as a battery control apparatus performs battery charging, according to an embodiment of the present disclosure;

FIG. 9 shows an example of a graph illustrating the relationship between OCV and SOC obtained as a battery control apparatus performs battery discharging, according to an embodiment of the present disclosure;

FIG. 10 shows an example of a flowchart illustrating a battery control method, according to an embodiment of the present disclosure; and

FIG. 11 shows a computing system associated with a battery control apparatus or battery control method, according to an embodiment of the present disclosure.

### DETAILED DESCRIPTION

Hereinafter, some embodiments of the present disclosure are described in detail with reference to the accompanying drawings. In adding reference numerals to components of each drawing, it should be noted that the same components include the same reference numerals, although they are indicated on another drawing. Furthermore, in describing the embodiments of the present disclosure, detailed descriptions associated with well-known functions or configurations have been omitted if they would have made subject matter of the present disclosure unnecessarily obscure or unclear.

In describing elements of an embodiment of the present disclosure, the terms first, second, A, B, (a), (b), and the like may be used herein. These terms are only used to distinguish one element from another element, but do not limit the corresponding elements irrespective of the nature, order, or priority of the corresponding elements. Furthermore, unless otherwise defined, all terms including technical and scientific terms used herein are to be interpreted as is customary in the art to which the present disclosure belongs. It should be understood that terms used herein are to be interpreted as including a meaning that is consistent with their meaning in the context of the present disclosure and the relevant art and should not be interpreted in an idealized or overly formal sense unless expressly so defined herein.

In various embodiments of the present disclosure, the term “module” used herein may include a unit, which is implemented with hardware, software, or firmware, and may be interchangeably used with the terms “logic”, “logical block”, “part”, or “circuit”. The “module” may be a minimum unit of an integrated part or may be a minimum unit of the part for performing one or more functions or a part thereof. In an embodiment, the module may be implemented in the form of an application-specific integrated circuit (ASIC). According to various embodiments, operations executed by modules, programs, or other components may be executed by a successive method, a parallel method, or a repeated method. Alternatively, at least one or more of the operations may be executed in another order or may be omitted, or one or more operations may be added.

Various embodiments of the present disclosure may be implemented with software (e.g., a program) including one or more instructions stored in a storage medium (e.g., an internal memory or an external memory) readable by a machine (e.g., a battery control apparatus 100). For example, the processor (e.g., the processor 110) of the machine (e.g., the battery control apparatus 100) may call at least one instruction of the stored one or more instructions from a storage medium and then may execute the at least one instruction. This enables the machine to operate to perform at least one function depending on the called at least one instruction. The one or more instructions may include a code generated by a complier or a code executable by an interpreter. The machine-readable storage medium may be provided in the form of a non-transitory storage medium. Herein, ‘non-transitory’ just means that the storage medium is a tangible device and does not include a signal (e.g., electromagnetic waves). This term does not distinguish between the case where data is semi-permanently stored in the storage medium and the case where the data is stored temporarily.

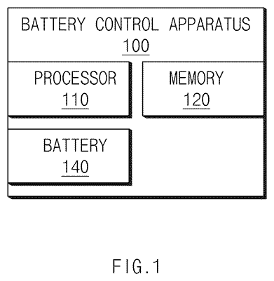

Hereinafter, embodiments of the present disclosure are described in detail with reference to FIGS. 1-11. When a component, device, module, controller, unit, element, or the like of the present disclosure is described as having a purpose or performing an operation, function, or the like, the component, device, module, controller, unit, element, or the like should be considered herein as being “configured to” meet that purpose or to perform that operation or function.

FIG. 1 shows an example of a block diagram associated with a battery control apparatus, according to an embodiment of the present disclosure.

Referring to FIG. 1, the battery control apparatus 100 according to an embodiment of the present disclosure may be implemented inside or outside a vehicle. Some of components included in the battery control apparatus 100 may be implemented inside or outside the vehicle. At this time, the battery control apparatus 100 may be integrated with internal control units of a vehicle and may be implemented with a separate device so as to be coupled with control units of the vehicle by a separate connection device. For example, the battery control apparatus 100 may further include components not shown in FIG. 1. For example, the battery control apparatus 100 may control at least one of operations of the vehicle by using a battery.

The battery control apparatus 100 according to an embodiment may include at least one of a processor 110, a memory 120, and/or a battery 140. The processor 110, the memory 120, and the battery 140 may be electronically and/or operably coupled with each other by an electronical component including a communication bus. Hereinafter, the fact that pieces of hardware are operably coupled may mean that a direct or indirect connection between the pieces of hardware is established by wired or wireless connection such that second hardware is controlled by first hardware among the pieces of hardware. Although shown based on different blocks, an embodiment is not limited thereto. For example, some (e.g., at least part of the processor 110, the memory 120, and a communication circuit (not shown)) of pieces of hardware in FIG. 1 may be included in a single integrated circuit, such as a system on a chip (SoC).

The processor 110 of the battery control apparatus 100 according to an embodiment may include a hardware component for processing data based on one or more instructions. The hardware component for processing data may include, for example, an arithmetic and logic unit (ALU), a floating point unit (FPU), a field programmable gate array (FPGA), a central processing unit (CPU), a micro controller unit (MCU), and/or an application processor (AP). The number of processors 110 may be one or more. For example, the processor 110 may include a structure of a multi-core processor including a dual core, a quad core, a hexa core, or an octa core.

The memory 120 of the battery control apparatus 100 according to an embodiment may include a hardware component for storing data and/or instructions that are to be input and/or output to the processor 110. For example, the memory 120 may include a volatile memory such as a random-access memory (RAM), and/or a non-volatile memory such as a read-only memory (ROM). For example, the volatile memory may include at least one of a dynamic RAM (DRAM), a static RAM (SRAM), a cache RAM, or a pseudo SRAM (PSRAM). For example, the non-volatile memory includes at least one of a programmable ROM (PROM), an erasable PROM (EPROM), an electrically erasable PROM (EEPROM), a flash memory, a hard disk, a compact disk, or an embedded multi-media card (eMMC).

The battery 140 of the battery control apparatus 100 according to an embodiment may include a battery pack, a battery cell, and/or a battery module. For example, the battery pack may consist of one or more unit cells. For example, the battery module may include one or more battery cells. For example, the battery cell may include a positive electrode, a negative electrode, and an electrolyte. For example, the battery pack may include a battery cell, a battery module, a battery management system (BMS), and/or a cooling system.

For example, the battery 140 may include one of a lithium ion (Li-ion) battery, a lithium ion (Li-ion) polymer battery, a lead storage battery, a nickel-cadmium (NiCd) battery, a nickel hydride (NiMH) battery, or a lithium-iron phosphate (LFP) battery.

For example, the battery 140 may include open-circuit voltage (OCV) characteristics and hysteresis characteristics. The battery control apparatus 100 may infer the state-of-charge (SOC) of the battery 140 based on OCV characteristics and hysteresis characteristics. The hysteresis characteristics may mean a phenomenon that the level of a cell voltage relaxes to a value smaller than a true OCV value for SOC after discharge.

The battery control apparatus 100 according to an embodiment may identify battery information including the voltage of the battery 140 and the current of the battery 140.

The battery control apparatus 100 according to an embodiment may obtain a hysteresis parameter according to each of a plurality of SOC sections of the battery by using battery information. Herein, the term ‘sections’ refers to state ranges or charge state ranges of a battery, such as might be shown on a diagram or graph indicating the charge state of a battery from 0% charged to 100% charged or the like.

For example, the hysteresis parameter may be obtained by performing at least one of an average OCV corresponding to the plurality of SOC sections, charging a battery, or discharging the battery, or any combination thereof, and may indicate a ratio between OCVs respectively corresponding to the plurality of SOC sections.

In an embodiment, the battery control apparatus 100 may identify the average OCV corresponding to all of the plurality of SOC sections by performing at least one of charging the battery 140 or discharging the battery 140, or any combination thereof, by using a designated current less than or equal to a threshold current.

In an embodiment, the battery control apparatus 100 may obtain the hysteresis parameter corresponding to each of the plurality of SOC sections by performing at least one of charging the battery 140 or discharging the battery 140, or any combination thereof, by using the current designated in each of the plurality of SOC sections.

In an embodiment, the battery control apparatus 100 may obtain the hysteresis parameter corresponding to each of the plurality of SOC sections by using the SOC change amount of the battery 140 in each of the plurality of SOC sections.

For example, because a voltage drop may occur if the battery control apparatus 100 applies a charging current or a discharging current of a battery to the battery based on an incremental OCV (IO), the battery control apparatus 100 may identify the average OCV based on a low current OCV (LO). For example, the battery control apparatus 100 may identify the average OCV based on a current integration method.

In an embodiment, the battery control apparatus 100 may identify the OCV corresponding to each of a plurality of SOC sections by using the average OCV corresponding to all of the plurality of SOC sections and by using the hysteresis parameter according to each of the plurality of SOC sections.

In an embodiment, the battery control apparatus 100 may obtain an equivalent model of the battery based on at least one of OCV corresponding to each of the plurality of SOC sections or battery information, or any combination thereof.

For example, the equivalent model of the battery may include an electrical equivalent circuit model (EECM). The EECM may include an OCV (e.g., an open-circuit voltage) model for identifying OCV, a Rint model for identifying a voltage drop, and/or a Thevenin model for identifying battery diffusion voltage characteristics.

For example, the battery control apparatus 100 may identify a terminal voltage of the battery by using an equivalent model. For example, the battery control apparatus 100 may identify the terminal voltage of the battery by using a look-up table (LUT) based on experimental data.

For example, the battery control apparatus 100 may identify an equivalent model parameter related to the equivalent model. For example, the battery control apparatus 100 may identify the equivalent model parameter by using the battery information. For example, the battery control apparatus 100 may identify an equivalent model parameter indicating the resistance of the equivalent model and/or an equivalent model parameter indicating the capacitance of the equivalent model by using the battery information. However, an embodiment is not limited thereto.

For example, the battery control apparatus 100 may identify the equivalent model parameter by using a recursive least square (RLS).

For example, the RLS may be used to estimate the battery model parameter by using OCV, which is converted from a battery SOC estimated value (or a prediction value), a module current, and voltage information of a battery cell. For example, the RLS may refer to a method that converts the least square method (LSM) into a recursive equation and may include a method of setting parameters of the equivalent model for minimizing the sum of squares of residuals between an equivalent model prediction value and an actual measured value.

For example, because the battery control apparatus 100 estimates an equivalent model parameter by using voltage information based on RLS, the battery control apparatus 100 may reduce an SOC estimation error caused by a temperature change in a battery.

In an embodiment, the battery control apparatus 100 may identify a hysteresis parameter corresponding to each of a plurality of SOC sections by using the equivalent model.

The battery control apparatus 100 according to an embodiment may identify the SOC of a battery by using the hysteresis parameter corresponding to each of the SOC sections and a Kalman filter (e.g., extended Kalman filter (EKF)).

For example, the Kalman filter may be the type of an adaptive control method and may include a recursive filter that estimates the internal state of a system disturbed by white noise based on the least square error and that estimates the state of a linear dynamical system. For example, the battery control apparatus 100 may perform linearization of a nonlinear system by using a Kalman filter to which a partial differentiation technique is applied. The battery control apparatus 100 may infer the SOC of the battery by linearizing OCV including nonlinear characteristics.

The battery control apparatus 100 according to an embodiment may infer the SOC of the battery relatively accurately, rather than using the average OCV corresponding to all of the plurality of SOC sections, by using the hysteresis parameter for each of the plurality of SOC sections.

In an embodiment, the battery control apparatus 100 may infer the SOC of a battery by applying a Kalman filter including different values to the plurality of SOC sections.

The battery control apparatus 100 according to an embodiment may identify a first hysteresis parameter corresponding to a first SOC section among the plurality of SOC sections. For example, the battery control apparatus 100 may identify a first OCV corresponding to the first SOC section by using the first hysteresis parameter and the average OCV corresponding to all of the plurality of SOC sections. For example, the battery control apparatus 100 may identify the SOC of the battery by applying a first Kalman filter related to a current integration method to the first OCV. The SOC of the battery may be included in the first SOC section. However, an embodiment is not limited thereto.

The battery control apparatus 100 according to an embodiment may classify the plurality of SOC sections into the first SOC section and a second SOC section based on the voltage characteristics of the battery. For example, the battery control apparatus 100 may identify the SOC of the battery by applying a second Kalman filter related to a measurement equation to a second OCV corresponding to the second SOC section. The SOC of the battery may be included in the second SOC section. However, an embodiment is not limited thereto.

For example, the voltage change rate of the first SOC section may be lower than the voltage change rate of the second SOC section. For example, a parameter indicating system noise and a parameter indicating measurement noise, which are included in the first Kalman filter, may be different from a parameter indicating system noise and a parameter indicating measurement noise, which are included in the second Kalman filter, respectively.

After identifying the SOC of the battery, the battery control apparatus 100 according to an embodiment may obtain another hysteresis parameter related to another SOC, which is to be identified after the SOC of the battery is identified, by using a hysteresis parameter corresponding to each of the plurality of SOC sections and by using an SOC change amount of the battery in each of the plurality of SOC sections. In other words, the battery control apparatus 100 may infer the SOC of the battery 140 in real time.

The battery control apparatus 100 according to an embodiment as described above may identify the SOC of the battery by using the OCV characteristics and hysteresis characteristics of the battery. The battery control apparatus 100 may use an equivalent model including a hysteresis model to identify the hysteresis characteristics. The battery control apparatus 100 may accurately identify the SOC of the battery and the terminal voltage of the battery by applying the hysteresis model to an algorithm using the RLS and the Kalman filter. For example, the battery control apparatus 100 may identify OCV by using the LO based on the RLS. For example, the battery control apparatus 100 may accurately infer the SOC of the battery by changing a noise value of the Kalman filter for each SOC section to reflect the low voltage change rate in a specific section of the SOC of the battery. The battery control apparatus 100 may reduce an SOC estimation error due to the flat voltage characteristics and hysteresis characteristics of the battery.

In other words, the battery control apparatus 100 may accurately identify the SOC of the battery by using a hysteresis parameter corresponding to each of the plurality of SOC sections based on the hysteresis characteristics of the battery and by using a Kalman filter corresponding to each of the plurality of SOC sections based on the voltage characteristics of the battery.

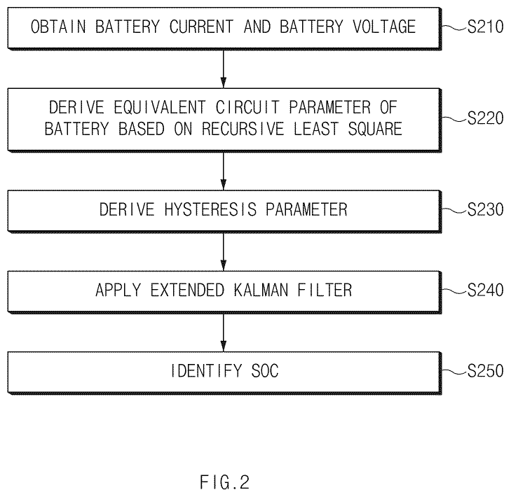

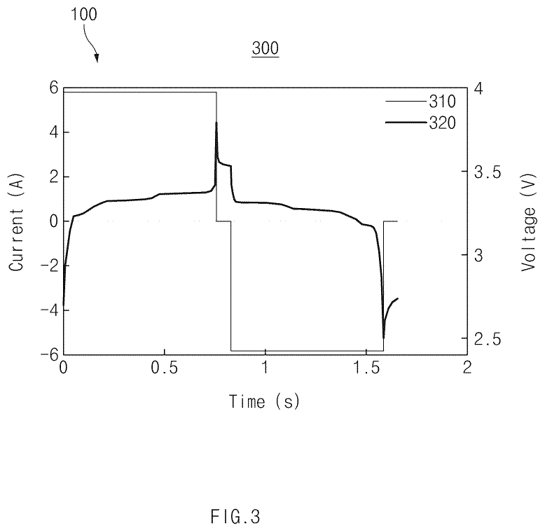

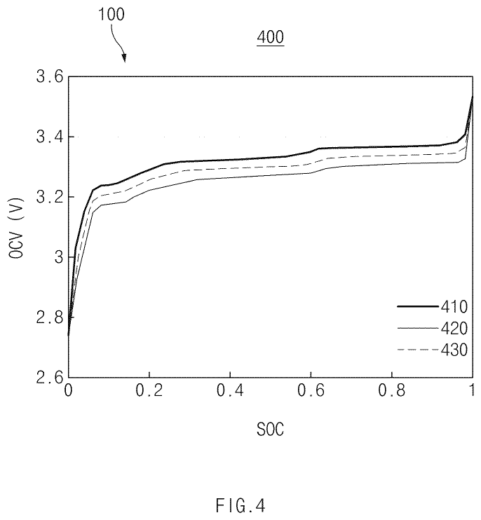

FIG. 2 shows an example of a flowchart illustrating an operation of a battery control apparatus, according to an embodiment of the present disclosure. FIG. 3 shows an example of a graph illustrating a battery current and a battery voltage, which are obtained by a battery control apparatus, according to an embodiment of the present disclosure. FIG. 4 shows an example of a graph illustrating a relationship between OCV and SOC obtained by a battery control apparatus, according to an embodiment of the present disclosure.

Hereinafter, it is assumed that the battery control apparatus 100 of FIG. 1 performs the process of FIG. 2. In addition, in a description of FIG. 2, it may be understood that an operation described as being performed by an apparatus is controlled by the processor 110 of the battery control apparatus 100. Each of the operations in FIG. 2 may be performed sequentially but the operations are not necessarily sequentially performed. For example, the order of operations may be changed, and at least two operations may be performed in parallel.

Referring to FIG. 2, in S210, a battery control apparatus according to an embodiment may obtain data (e.g., battery information) indicating a battery current and a battery voltage. For example, the battery control apparatus may obtain the battery information indicating the battery voltage and the battery current, which are obtained while a vehicle is driving, by using a battery management system (BMS). The battery control apparatus may obtain an equivalent model parameter of an equivalent model corresponding to a battery by using the battery information.

Referring to FIG. 2, in S220, the battery control apparatus according to an embodiment may obtain the equivalent model parameter of the battery based on RLS.

For example, a battery control apparatus may identify OCV by performing battery charging and/or battery discharging by using a designated current (e.g., LO), which is smaller than or equal to a threshold current (e.g., 0.05 C-rate), based on LO. For example, the battery control apparatus may obtain information indicating changes in OCV (e.g., an open-circuit voltage) for each of a plurality of SOC sections based on the LO. For example, the battery control apparatus may obtain relatively accurate information indicating a change in OCV for each of the SOC sections, by minimizing the influence due to the internal resistance of the battery based on the LO.

Referring to FIG. 3, a graph 300 shows a relationship between the current of a battery and the voltage of the battery, which are obtained as the battery control apparatus 100 charges and/or discharges the battery based on the LO. For example, the graph 300 may include a plot 310 indicating current and a plot 320 indicating voltage. The battery control apparatus 100 may obtain the OCV of the battery for the SOC of the battery by using battery LO information corresponding to the graph 300. The relationship between the SOC of the battery and the OCV of the battery obtained as the battery control apparatus 100 charges and/or discharges the battery based on the LO may be expressed as a graph 400 in FIG. 4.

Referring to FIG. 4, the graph 400 may include a plot 410 indicating the relationship between the OCV of the battery and the SOC of the battery identified while the battery is charged, a plot 420 indicating the relationship between the OCV of the battery and the SOC of the battery identified while the battery is discharged, and a plot 430 indicating an average value between the two graphs 410 and 420.

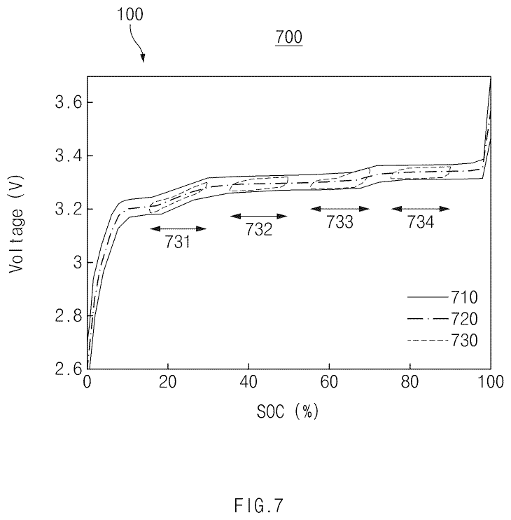

For example, an operation of the battery control apparatus 100 obtaining information indicating the relationship between SOC and OCV by identifying a plurality of SOC sections is described in more detail below with reference to FIG. 7.

Returning to FIG. 2, in S230, the battery control apparatus according to an embodiment may obtain a hysteresis parameter. The battery control apparatus may obtain the hysteresis parameter by using a hysteresis model based on hysteresis characteristics. The battery control apparatus may obtain the hysteresis parameter corresponding to each of the plurality of SOC sections by dividing the SOC of the battery into the plurality of SOC sections.

Referring to FIG. 2, in S240, the battery control apparatus according to an embodiment may apply an extended Kalman filter to the OCV (or SOC corresponding to OCV) and/or the hysteresis parameter. The battery control apparatus may apply the extended Kalman filter with different values for each of the plurality of SOC sections.

Referring to FIG. 2, in S250, the battery control apparatus according to an embodiment may identify the SOC of the battery. For example, the battery control apparatus may provide a user with the identified SOC of the battery. For example, the battery control apparatus may display a visual object indicating the SOC of the battery on a display. The battery control apparatus may transmit a signal indicating the SOC of the battery to a user terminal.

For example, the battery control apparatus may obtain the drivable distance of a vehicle depending on the identified SOC of the battery. The battery control apparatus may notify the user of the obtained drivable distance of the vehicle.

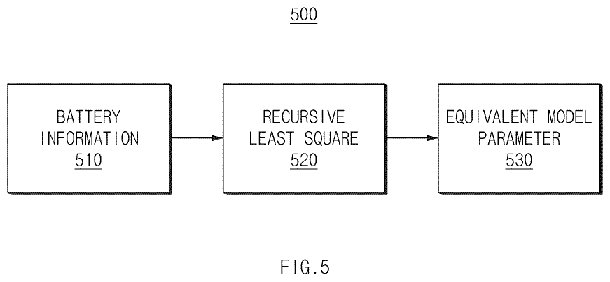

FIG. 5 shows an example 500 of a block diagram for describing an operation in which a battery control apparatus obtains an equivalent model of a battery, according to an embodiment of the present disclosure. The battery control apparatus 100 of FIG. 5 may be referenced to the battery control apparatus 100 of FIG. 1.

Referring to FIG. 5, in the example 500, the battery control apparatus 100 may obtain battery information 510. The battery information 510 may include data indicating a battery current and a battery voltage, which are obtained while a vehicle is driving. The battery information 510 may include the data indicating the battery current and the battery voltage obtained by performing battery charging and/or battery discharging based on LO. The battery voltage may include battery OCV.

Referring to FIG. 5, in the example 500, the battery control apparatus 100 may obtain an equivalent model parameter 530 by performing RLS 520 by using the battery information 510. The equivalent model may include an equivalent circuit of a battery indicating the battery.

The battery control apparatus according to an embodiment may obtain a transfer function for the RLS 520 by using overpotential indicating a voltage level changed by current. The overpotential may be expressed as Equation 1.

$${V}_{q} = {V}_{t} - OC V \qquad [ Equation 1 ]$$

Referring to Equation 1, V_{q} may denote overvoltage. Vₜ may denote the voltage of an equivalent model of a battery. OCV may denote the OCV of the battery.

For example, the battery control apparatus 100 may obtain Equation 2 and/or Equation 3 by using current and a transfer function according to an input and an output of the overpotential.

$${V}_{q , k} = - {a}_{1} {V}_{q , k - 1} + {b}_{0} {I}_{k} - {b}_{1} {I}_{k - 1} \qquad [ Equation 2 ]$$

Referring to Equation 2, a₁, b₀, and b₁ may denote coefficients of the overpotential. The battery control apparatus 100 may infer a₁, b₀, and b₁ based on the RLS 520. Equation 2 may be expressed as Equation 3 below.

$${V}_{q , k} = {[ {V}_{q , k - 1} , {I}_{k} , {I}_{k - 1} ] [ - {a}_{1} , {b}_{0} , {b}_{1} ]}^{T} = {φ}_{k} {θ}_{k}^{T} \qquad [ Equation 3 ]$$

Referring to Equation 3,

$${φ}_{k} {θ}_{k}^{T}$$

may denote an estimated voltage of the battery. Each of

$${θ}_{k}^{T}$$

and φₖ may denote a parameter related to RLS. For example, the battery control apparatus may identify

$${θ}_{k}^{T}$$

and φₖ based on at least one of a battery current (e.g., Iₖ in Equation 3), OCV, or a coefficient of the overpotential, or any combination thereof. However, an embodiment is not limited thereto.

For example, the coefficient of the overpotential may be expressed as Equation 4 through Equation 7. a₁ may be expressed as Equation 4.

$${a}_{1} = \frac{{t}_{s}}{{C}_{1} * {R}_{1}} - 1 \qquad [ Equation 4 ]$$

Referring to Equation 4, C₁ may denote an equivalent model parameter (e.g., capacitance) of the battery identified based on the battery information obtained while a vehicle is driving, R₁ may denote an equivalent model parameter (e.g., resistance) of the battery identified based on the battery information obtained while the vehicle is driving, tₛ may denote a parameter related to the battery equivalent model, and b₀ may be expressed as Equation 5.

$${b}_{0} = {R}_{0} \qquad [ Equation 5 ]$$

Referring to Equation 5, R₀ may denote an equivalent model parameter (e.g., resistance) obtained as the battery control apparatus charges or discharges the battery based on the LO. Also, b₁ may be expressed as Equation 6.

$${b}_{1} = - {R}_{0} + \frac{{t}_{s}}{{C}_{1}} + \frac{{t}_{s} {R}_{0}}{{C}_{1} {R}_{0}} \qquad [ Equation 6 ]$$

For example, in the equivalent model parameter, C₁ and R₁ may be connected in parallel with each other, and C₁ and R₁, which are connected in parallel with each other, and R₀ may be connected in series. However, an embodiment is not limited thereto.

The battery control apparatus 100 according to an embodiment may identify an error between the actual value and the estimated value of the voltage of the battery by using Equation 1 to Equation 6 based on RLS. The error may be expressed as Equation 7.

$${ε}_{k} = {V}_{q , k} - {φ}_{k} {θ}_{k - 1}^{T} \qquad [ Equation 7 ]$$

Referring to Equation 7, εₖ may denote the error between the actual value and the estimated value of the voltage of the battery. The battery control apparatus may identify a gain (or weight) and an error covariance by using Equation 7. The gain may be expressed as Equation 8, and the error covariance may be expressed as Equation 9.

$${K}_{k} = \frac{{P}_{k - 1} {φ}_{k}}{λ + {φ}_{k}^{T} {P}_{k - 1} {φ}_{k}} \qquad [ Equation 8 ]$$

Referring to Equation 8, λ may denote a forgetting factor. The forgetting factor may be used to determine the amount for using specific data.

$${P}_{k} = \frac{( 1 - {K}_{k} {φ}_{k}^{T} ) {P}_{k - 1}}{λ} \qquad [ Equation 9 ]$$

Referring to Equation 9, Pₖ may denote the error covariance.

For example, the battery control apparatus may update the equivalent model parameters by using Equation 7 to Equation 9. For example, the battery control apparatus may update the equivalent model parameters by using the gain and the error.

For example, the battery control apparatus may reflect state changes according to charging (or discharging) of the battery by feeding back previous parameter values. In other words, the battery control apparatus may prevent rapid changes in OCV if the sign of current changes due to charging or discharging of the battery.

For example, the battery control apparatus 100 may perform the update by using Equation 10.

$${θ}_{k}^{T} = {θ}_{k - 1}^{T} + {K}_{k} {ε}_{k} \qquad [ Equation 10 ]$$

For example, the equivalent model parameters may be expressed as Equation 11 through Equation 13.

$${R}_{0} = {b}_{0} \qquad [ Equation 11 ]$$

$${R}_{1} = \frac{{b}_{1} - {a}_{1} {b}_{0}}{1 - {a}_{1}} \qquad [ Equation 12 ]$$

$${C}_{1} = \frac{{t}_{s}}{{b}_{1} - {a}_{1} {b}_{0}} \qquad [ Equation 13 ]$$

The battery control apparatus 100 according to an embodiment may obtain the OCV of the battery and/or the SOC of the battery by updating the equivalent model parameters in real time by using Equation 11 through Equation 13. Data indicating the relationship between the OCV of the battery and the SOC of the battery obtained by the battery control apparatus 100 by using the equivalent model parameters may be represented as shown in the graph 400 of FIG. 4.

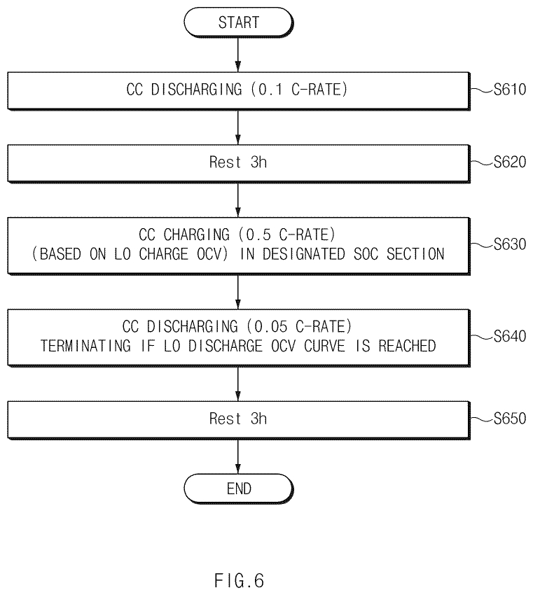

Hereinafter, an operation in which the battery control apparatus 100 according to an embodiment obtains a hysteresis parameter for each of the SOC sections is described below with reference to FIG. 6.

FIG. 6 shows an example of a flowchart illustrating an operation of a battery control apparatus, according to an embodiment of the present disclosure. Hereinafter, it is assumed that the battery control apparatus 100 of FIG. 1 performs the process of FIG. 6. In addition, in a description of FIG. 6, it may be understood that an operation described as being performed by an apparatus is controlled by the processor 110 of the battery control apparatus 100. Each of the operations in FIG. 6 may be performed sequentially but the operations are not necessarily sequentially performed. For example, the order of operations may be changed, and at least two operations may be performed in parallel. For example, at least one of the operations in FIG. 6 may be related to S230 in FIG. 2. For example, at least one of the operations in FIG. 6 may include an operation in which the battery control apparatus obtains the relationship between the OCV of the battery and the SOC of the battery based on LO.

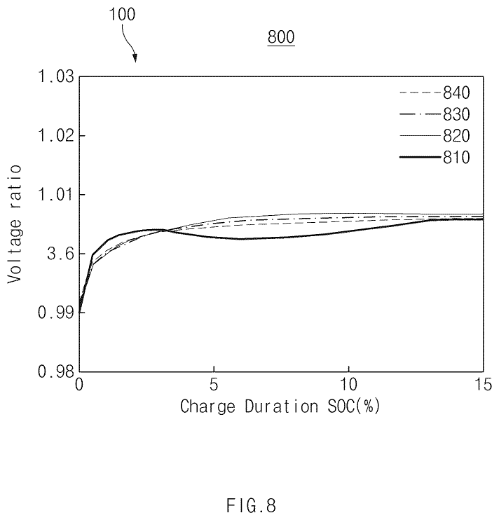

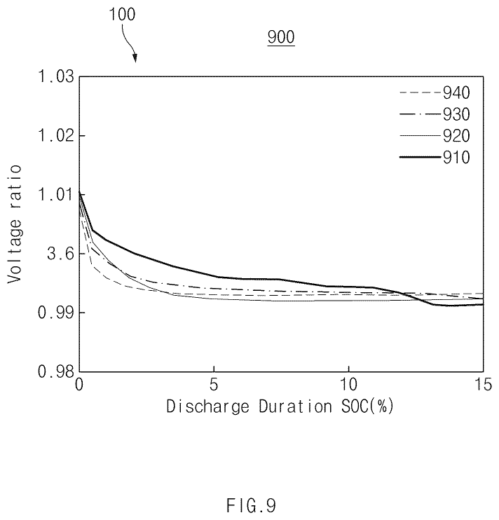

FIG. 7 shows an example of a graph illustrating the relationship between OCV and SOC corresponding to each of a plurality of SOC sections obtained by a battery control apparatus, according to an embodiment of the present disclosure. FIG. 8 shows an example of a graph showing the relationship between OCV and SOC obtained as a battery control apparatus performs battery charging, according to an embodiment of the present disclosure. FIG. 9 shows an example of a graph showing the relationship between OCV and SOC obtained as a battery control apparatus performs battery discharging, according to an embodiment of the present disclosure.

Referring to FIG. 6, in S610, the battery control apparatus according to an embodiment may discharge a battery (e.g., constant current (CC) discharge). The battery control apparatus may discharge the battery based on current with a specified value (e.g., 0.1 C-rate).

For example, to perform battery discharging and battery charging for each of a plurality of SOC sections, the battery control apparatus may discharge the battery such that the SOC of the battery is included in a first SOC section among the plurality of SOC sections. However, an embodiment is not limited thereto.

Referring to FIG. 6, in S620, the battery control apparatus 100 according to an embodiment may stop the use of the battery during a specified time (e.g., 3 hours). For example, to reduce an error based on temperature changes of the battery according to battery discharging, the battery control apparatus 100 may stop the use of the battery.

Referring to FIG. 6, in S630, the battery control apparatus 100 according to an embodiment may charge the battery (e.g., CC charging) based on a designated current smaller than or equal to a threshold current in a designated SOC section (e.g., a section including 50%).

For example, in the entire range of the SOC of the battery (e.g., 0% to 100%), the battery control apparatus 100 may identify the plurality of SOC sections depending on the designated range (e.g., about 15%). Battery usage may vary depending on the plurality of SOC sections. The plurality of SOC sections may include a first section including first SOC (e.g., about 30%), a second section including second SOC (e.g., about 50%), a third section including third SOC (e.g., about 70%), and/or a fourth section including fourth SOC (e.g., about 90%).

For example, in the first section, the battery control apparatus 100 may charge the battery based on the designated current smaller than or equal to the threshold current. For example, the battery control apparatus 100 may charge the battery such that the SOC of the battery does not deviate from the first section. However, an embodiment is not limited thereto.

Referring to FIG. 6, in S640, the battery control apparatus 100 according to an embodiment may discharge the battery in the designated SOC section. The battery control apparatus 100 may stop discharging the battery if identifying a LO discharge OCV Curve. The LO discharge OCV Curve may include a section where the OCV of the battery changes relatively rapidly, in the designated SOC section based on hysteresis characteristics.

Referring to FIG. 6, in S650, the battery control apparatus according to an embodiment may stop the use of the battery for a designated time (e.g., about 3 hours).

For example, the battery control apparatus 100 may repeatedly perform operations S610 to S650 for each of the SOC sections. The battery control apparatus 100 may obtain a hysteresis parameter corresponding to each of the SOC sections by repeatedly performing operations S610 to S650 for each of the SOC sections.

Referring to FIG. 7, a graph 700 illustrating a hysteresis curve for the plurality of SOC sections by the battery control apparatus according to an embodiment is shown. The graph 700 may include a plot 710 indicating a hysteresis curve for all of the SOC sections of the battery, a plot 720 indicating the relationship between the average OCV and SOC for all of the SOC sections of the battery, and a plot 730 indicating a hysteresis curve for each of the SOC sections.

For example, the graph 730 may include a hysteresis curve for a first section 731, a hysteresis curve for a second section 732, a hysteresis curve for a third section 733, and/or a hysteresis curve for a fourth section 734 among the plurality of SOC sections. The hysteresis curve corresponding to each of the SOC sections may be referred to as a “minor loop” from the perspective included in a hysteresis curve corresponding to the entire SOC.

For example, the battery control apparatus 100 may obtain a hysteresis parameter corresponding to each of the SOC sections.

For example, the hysteresis parameter corresponding to each of the SOC sections may indicate OCV of each of the SOC sections for the average OCV of all of the SOC sections.

In an embodiment, a graph indicating the hysteresis parameter obtained as the battery control apparatus 100 charges the battery based on LO may be shown as a graph 800 in FIG. 8.

Referring to FIG. 8, the graph 800 may indicate a hysteresis parameter according to the charging of the battery. For example, the graph 800 may include a plot 810 indicating a hysteresis parameter corresponding to the first section 731, a plot 820 indicating a hysteresis parameter corresponding to the second section 732, a plot 830 indicating a hysteresis parameter corresponding to the third section 733, and/or a plot 840 indicating a hysteresis parameter corresponding to the fourth section 734.

For example, the hysteresis parameter obtained by charging the battery may include a value greater than the average OCV (e.g., about 1). However, an embodiment is not limited thereto.

In an embodiment, a graph indicating the hysteresis parameter obtained as the battery control apparatus 100 discharges the battery based on LO may be shown as a graph 900 in FIG. 9.

Referring to FIG. 9, the graph 900 may indicate a hysteresis parameter according to the discharging of the battery. For example, the graph 900 may include a plot 910 indicating a hysteresis parameter corresponding to the first section 731, a plot 920 indicating a hysteresis parameter corresponding to the second section 732, a plot 930 indicating a hysteresis parameter corresponding to the third section 733, and/or a plot 940 indicating a hysteresis parameter corresponding to the fourth section 734.

For example, the hysteresis parameter obtained by discharging the battery may include a value smaller than the average OCV (e.g., about 1). However, an embodiment is not limited thereto.

The battery control apparatus 100 according to an embodiment may perform modeling for linearizing a hysteresis characteristic curve according to the SOC change amount of each of the charging state of the battery or the discharging state of the battery by using the hysteresis parameter. For example, the battery control apparatus 100 may obtain the hysteresis parameter by using feedback data based on Equation 14.

$${δ}_{k} = {δ}_{k - 1} + \vert \frac{{I}_{k} \times Δ t}{{C}_{n}} \vert \qquad [ Equation 14 ]$$

Referring to Equation 14, δₖ may denote a hysteresis parameter, and δₖ₋₁ may denote a value before feedback of the hysteresis parameter. For example,

$$\vert \frac{{I}_{k} \times Δt}{{C}_{n}} \vert$$

may denote the SOC change amount of the battery in the designated section, and

$$\frac{{I}_{k} \times Δ t}{{C}_{n}}$$

may denote a battery current for battery capacity and a time change amount. However, an embodiment is not limited thereto. The designated section may vary depending on whether the battery is in a charging state or a discharging state. The designated section may include the first through fourth sections 731-734. In other words, if the battery control apparatus is in a charging state and the SOC of the battery is included in the first section, the battery control apparatus may obtain the hysteresis parameter corresponding to the plot 810 of FIG. 8.

For example, the battery control apparatus 100 may update the hysteresis parameter by using feedback data, thereby preventing rapid OCV changes.

The battery control apparatus 100 according to an embodiment may identify OCV by using the hysteresis parameter corresponding to each of the SOC sections. For example, the battery control apparatus 100 may identify OCV based on Equation 15.

$${OCV}_{SOC} = {δ}_{k} \times {Average\_OCV}_{SOC} \qquad [ Equation 15 ]$$

Referring to Equation 15, OCV_{SOC} may denote OCV corresponding to each of the SOC sections and OCV_{SOC} may denote OCV to which hysteresis characteristics are reflected. Also, Average_{OCV}_{_{SOC}} may represent the average OCV corresponding to all of the plurality of SOC sections.

The battery control apparatus 100 according to an embodiment may accurately identify (or estimate) the SOC of the battery by applying a Kalman filter to OCV and SOC.

In an embodiment, the battery control apparatus 100 may identify the SOC of the battery by applying different Kalman filters for each of the SOC sections based on a flat voltage characteristic section of the battery.

For example, the battery control apparatus 100 may identify the SOC of the battery by using a Kalman filter with different noise parameters for each of the SOC sections.

For example, the Kalman filter may include system noise and measurement noise. For example, the Kalman filter may include a first Kalman filter for increasing the utilization rate of a current integration method and a second Kalman filter for increasing the utilization rate of a measurement equation. A value (e.g., 0.1) of the system noise and a value (e.g., [1e−9 0; 0 0.2]) of the measurement noise included in the first Kalman filter may be different from a system noise value (e.g., 0.01) and a measurement noise value (e.g., [1e−8 0; 0 0.1]) included in the second Kalman filter, respectively.

For example, the first Kalman filter may be used to identify SOC in a SOC section (e.g., 20% to 80%) where a voltage change rate of the battery is relatively low. The second Kalman filter may be used to identify SOC in a SOC section (e.g., 0% to 20% or 80% to 100%) where the voltage change rate of the battery is relatively high.

The battery control apparatus 100 according to an embodiment may identify a first hysteresis parameter corresponding to a first SOC section among the plurality of SOC sections. The battery control apparatus 100 may identify first OCV corresponding to the first SOC section by using the first hysteresis parameter and the average OCV corresponding to all of the plurality of SOC sections. The battery control apparatus 100 may identify the SOC of the battery by applying the first Kalman filter associated with a current integration method to the first OCV. The battery control apparatus 100 according to an embodiment may identify the SOC of the battery by applying a second Kalman filter associated with a measurement equation to second OCV (e.g., a value obtained by multiplying the second hysteresis parameter corresponding to the second SOC section and the average OCV) corresponding to the second SOC section distinct from the first SOC section. However, an embodiment is not limited thereto.

The battery control apparatus 100 according to an embodiment may identify the SOC of the battery or the voltage (e.g., a Thevenin voltage) of the equivalent model of the battery by using Equation 16 indicating the state equation of the Kalman filter.

$$[ Equation 16 ]$$

$$[ \begin{matrix}{SOC}_{k} \\ {V}_{1 , k}\end{matrix} ] = [ \begin{matrix}1 & 0 \\ 0 & exp ( - \frac{Δ t}{{R}_{1} {C}_{1}} )\end{matrix} ] [ \text{} \begin{matrix}{SOC}_{k - 1} \\ {V}_{1 , k - 1}\end{matrix} ] + [ \text{} \begin{matrix}\frac{- Δ t}{Q} \\ {R}_{1} ( 1 + exp ( - \frac{Δ t}{{R}_{1} {C}_{1}} )\end{matrix} ] \cdot {i}_{k - 1}$$

Referring to Equation 16, the battery control apparatus 100 may apply an initial value of OCV and an initial value of SOC, thereby reducing an initial error and an SOC error based on an OCV difference according to previous charge/discharge history.

For example, Equation 16 may be summarized as Equation 17 indicating the measurement equation of the Kalman filter.

$${V}_{t , k} = OCV ( {SOC}_{k} ) + {R}_{0} {i}_{k} + {R}_{1} {i}_{{R}_{1} , k} + {V}_{H} \qquad [ Equation 17 ]$$

As described above, the battery control apparatus 100 according to an embodiment may calculate the measurement equation of the Kalman filter by using the equivalent model parameter updated based on RLS. The battery control apparatus 100 may identify an estimated value and error covariance based on RLS through previous data (e.g., feedback data). The battery control apparatus 100 may obtain the Kalman gain (e.g., Kₖ in Equation 8) based on the error covariance and the measurement equation. For example, the battery control apparatus 100 may identify an error (e.g., εₖ in Equation 7) by using a terminal voltage (e.g., V_{t,k} in Equation 17) through the estimated value, the measurement equation, and the equivalent model. For example, the battery control apparatus 100 may obtain an updated SOC by using the estimated value and the error covariance, which are obtained through the error and a Kalman gain.

In an embodiment, the battery control apparatus 100 may accurately infer Soc by applying different Kalman filters for each of the SOC sections.

For example, a first error (e.g., 1.6) of SOC obtained as the battery control apparatus uses a hysteresis parameter may be smaller than a second error (e.g., 2.7) of SOC obtained by not using the hysteresis parameter.

For example, a third error (e.g., 0.5) of SOC obtained as the battery control apparatus applies different Kalman filters for each of the SOC sections may be smaller than a fourth error (e.g., 1.6) of SOC obtained by applying one Kalman filter.

As described above, the battery control apparatus 100 according to an embodiment may accurately identify the SOC of the battery by obtaining a hysteresis parameter for each of the SOC sections and applying different Kalman filters for each of the SOC sections.

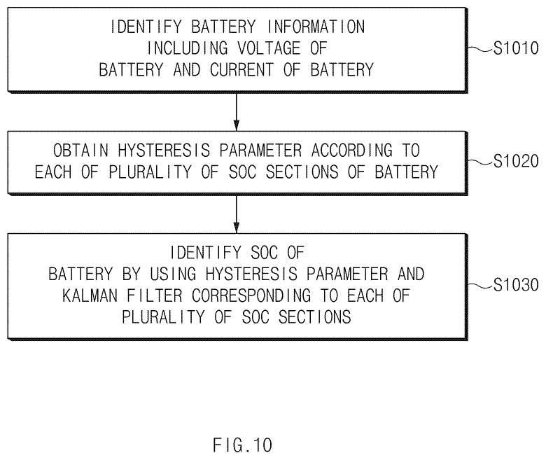

FIG. 10 shows an example of a flowchart illustrating a battery control method, according to an embodiment of the present disclosure. Hereinafter, it is assumed that the battery control apparatus 100 of FIG. 1 performs the process of FIG. 10. In addition, in a description of FIG. 10, it may be understood that an operation described as being performed by an apparatus is controlled by the processor 110 of the battery control apparatus 100. Each of the operations in FIG. 10 may be performed sequentially but the operations are not necessarily sequentially performed. For example, the order of operations may be changed, and at least two operations may be performed in parallel.

Referring to FIG. 10, in S1010, the battery control method according to an embodiment may include an operation of identifying battery information including the voltage of a battery and the current of the battery. The battery control method may include an operation of obtaining an equivalent model parameter of the battery by using the battery information including the voltage of the battery and the current of the battery.

For example, the battery control apparatus may update an equivalent model parameter (e. g., Equation 11 through Equation 13) by using Equation 1 through Equation 10.

For example, operation S1010 may be associated with operation S210 and/or operation S220 of FIG. 2.

Referring to FIG. 10, in S1020, the battery control method according to an embodiment may include an operation of obtaining a hysteresis parameter according to each of the plurality of SOC sections of the battery. An operation of obtaining the hysteresis parameter for each of the plurality of SOC sections may include an operation of obtaining OCV for each of the plurality of SOC sections.

For example, the battery control apparatus may obtain OCV, to which hysteresis characteristics are reflected, by using Equation 14 and Equation 15.

For example, operation S1020 may be associated with at least one of the operations in FIG. 6. For example, operation S1020 may be associated with operation S230 in FIG. 2.

Referring to FIG. 10, in S1030, the battery control method according to an embodiment may include an operation of identifying the SOC of the battery by using a hysteresis parameter and a Kalman filter corresponding to each of the plurality of SOC sections. The battery control method according to an embodiment may include an operation of identifying the SOC of the battery by using the Kalman filter corresponding to each of the plurality of SOC sections.

For example, an operation of identifying the SOC of the battery may include an operation of identifying the SOC of the battery while the battery control apparatus performs at least one of charging the battery, or discharging the battery, or any combination thereof.

For example, the hysteresis parameter corresponding to each of the plurality of SOC sections may include different values depending on the charging state of the battery or the discharging state of the battery.

For example, an operation of identifying the SOC of the battery may include an operation of identifying the SOC of the battery by using the hysteresis parameter and the Kalman filter according to the charging state of the battery or the discharging state of the battery.

For example, the battery control apparatus may identify the SOC of the battery based on Equation 16 and Equation 17.

For example, operation S1030 may be associated with operation S240 and/or operation S250 of FIG. 2.

As described above, to reflect voltage characteristics of the battery, the battery control method according to an embodiment may accurately identify the SOC of the battery by using the Kalman filter corresponding to each of the plurality of SOC sections and the hysteresis characteristic corresponding to each of the plurality of SOC sections.

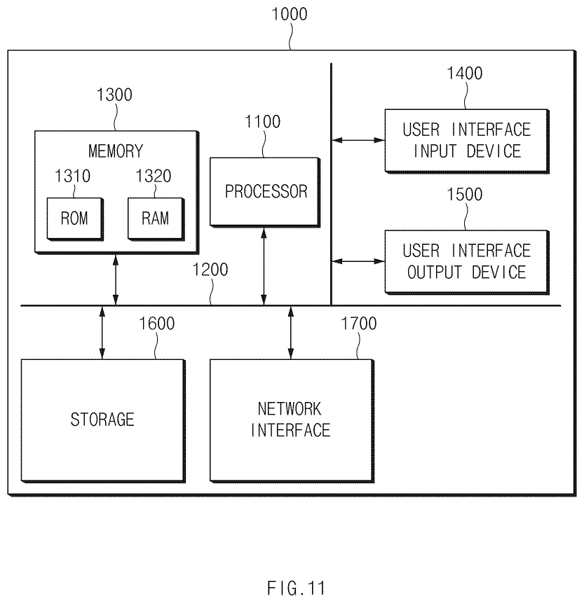

FIG. 11 shows a computing system associated with a battery control apparatus or battery control method, according to an embodiment of the present disclosure.

Referring to FIG. 11, the computing system 1000 may include at least one processor 1100, a memory 1300, a user interface input device 1400, a user interface output device 1500, storage 1600, and a network interface 1700 connected through a system bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) 1310 and a RAM (Random Access Memory) 1320.

Thus, the operations of the method or the algorithm described in connection with the embodiments disclosed herein may be embodied directly in hardware or a software module executed by the processor 1100, or in a combination thereof. The software module may reside on a storage medium (i.e., the memory 1300 and/or the storage 1600) such as a RAM, a flash memory, a ROM, an EPROM, an EEPROM, a register, a hard disk, a removable disk, and a CD-ROM.

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

The above description is merely an example of the technical idea of the present disclosure, and various modifications and modifications may be made by one of ordinary skill in the art without departing from the essential characteristic of the present disclosure.

Accordingly, embodiments of the present disclosure are intended not to limit but to explain the technical idea of the present disclosure, and the scope and spirit of the present disclosure is not limited by the above embodiments. The scope of protection of the present disclosure should be construed by the attached claims, and all equivalents thereof should be construed as being included within the scope of the present disclosure.

The present technology may obtain a hysteresis parameter for each of a plurality of SOC sections.

The present technology may apply an extended Kalman filter with different noise parameters for each of the SOC sections.

Moreover, the present technology may identify the SOC of a battery by using the hysteresis parameter and the extended Kalman filter.

Further, a variety of effects directly or indirectly understood through the present disclosure may be provided.

Hereinabove, although the present disclosure was described with reference to example embodiments and the accompanying drawings, the present disclosure is not limited thereto. The disclosed embodiments may be variously modified and altered by those of ordinary skill in the art to which the present disclosure pertains without departing from the spirit and scope of the present disclosure claimed in the following claims.

What is claimed is:

1. A battery control apparatus comprising:
a battery;
a processor; and
a memory,
wherein the processor is configured to
identify battery information including voltage of the battery and current of the battery,
identify an average open-circuit voltage (OCV) corresponding to all of a plurality of state-of-charge (SOC) sections by performing at least one of charging the battery or discharging the battery, or any combination thereof, by using a designated current smaller than or equal to a threshold current,
obtain a hysteresis parameter according to each of the plurality of SOC sections of the battery by using at least one of the battery information or the average OCV, or any combination thereof, and
identify a SOC of the battery while performing at least one of charging the battery or discharging the battery, or any combination thereof, by using the hysteresis parameter and a Kalman filter according to each of the plurality of SOC sections.

2. The battery control apparatus of claim 1, wherein the hysteresis parameter indicates a ratio between OCVs respectively corresponding to the plurality of SOC sections, which are obtained while performing at least one of the average OCV, charging the battery, or discharging the battery, or any combination thereof.

3. The battery control apparatus of claim 1, wherein the processor is further configured to:
identify an OCV corresponding to each of the plurality of SOC sections by using the average OCV corresponding to all of the plurality of SOC sections and the hysteresis parameter according to each of the plurality of SOC sections.

4. The battery control apparatus of claim 3, wherein the processor is further configured to:
obtain an equivalent model of the battery based on at least one of the OCV corresponding to each of the plurality of SOC sections or the battery information, or any combination thereof; and
obtain the hysteresis parameter corresponding to each of the plurality of SOC sections by using the equivalent model.

5. The battery control apparatus of claim 1, wherein the processor is configured to:
obtain the hysteresis parameter corresponding to each of the plurality of SOC sections by performing at least one of charging the battery or discharging the battery, or any combination thereof, by using the designated current in each of the plurality of SOC sections.

6. The battery control apparatus of claim 1, wherein the processor is configured to:
obtain the hysteresis parameter corresponding to each of the plurality of SOC sections by using a SOC change amount of the battery in each of the plurality of SOC sections.

7. The battery control apparatus of claim 1, wherein the processor is configured to:
identify a first hysteresis parameter corresponding to a first SOC section among the plurality of SOC sections;
identify a first OCV corresponding to the first SOC section by using the first hysteresis parameter and the average OCV corresponding to all of the plurality of SOC sections; and
identify the SOC of the battery by applying a first Kalman filter associated with a current integration method to the first OCV.

8. The battery control apparatus of claim 7, wherein the processor is configured to:
classify the plurality of SOC sections into the first SOC section and a second SOC section based on voltage characteristics of the battery; and
identify the SOC of the battery by applying a second Kalman filter associated with a measurement equation to second OCV corresponding to the second SOC section.

9. The battery control apparatus of claim 8, wherein a voltage change rate of the first SOC section is lower than a voltage change rate of the second SOC section.

10. The battery control apparatus of claim 1, wherein the processor is configured to:
after identifying the SOC of the battery, obtain another hysteresis parameter associated with another SOC, which is to be identified after the SOC of the battery is identified, by using the hysteresis parameter corresponding to each of the plurality of SOC sections and a SOC change amount of the battery corresponding to each of the plurality of SOC sections.

11. A battery control method, the method comprising:
identifying battery information including voltage of a battery and current of the battery;
identifying average open-circuit voltage (OCV) corresponding to all of a plurality of state-of-charge (SOC) sections by performing at least one of charging the battery or discharging the battery, or any combination thereof, by using a designated current smaller than or equal to a threshold current;
obtaining a hysteresis parameter according to each of the plurality of SOC sections of the battery by using at least one of the battery information or the average OCV, or any combination thereof; and
identifying a SOC of the battery while performing at least one of charging the battery or discharging the battery, or any combination thereof, by using the hysteresis parameter and a Kalman filter according to each of the plurality of SOC sections.

12. The method of claim 11, wherein the hysteresis parameter indicates a ratio between OCVs respectively corresponding to the plurality of SOC sections, which are obtained while performing at least one of the average OCV, charging the battery, or discharging the battery, or any combination thereof.

13. The method of claim 11, wherein identifying the average OCV further includes:
identifying an OCV corresponding to each of the plurality of SOC sections by using the average OCV corresponding to all of the plurality of SOC sections and the hysteresis parameter according to each of the plurality of SOC sections.

14. The method of claim 13, wherein obtaining the hysteresis parameter according to each of the plurality of SOC sections further includes:
obtaining an equivalent model of the battery based on at least one of the OCV corresponding to each of the plurality of SOC sections or the battery information, or any combination thereof; and
obtaining the hysteresis parameter corresponding to each of the plurality of SOC sections by using the equivalent model.

15. The method of claim 11, wherein obtaining the hysteresis parameter according to each of the plurality of SOC sections includes:
obtaining the hysteresis parameter corresponding to each of the plurality of SOC sections by performing at least one of charging the battery or discharging the battery, or any combination thereof, by using the designated current in each of the plurality of SOC sections.

16. The method of claim 11, wherein obtaining the hysteresis parameter according to each of the plurality of SOC sections includes:
obtaining the hysteresis parameter corresponding to each of the plurality of SOC sections by using a SOC change amount of the battery in each of the plurality of SOC sections.

17. The method of claim 11, wherein identifying the SOC of the battery includes:
identifying a first hysteresis parameter corresponding to a first SOC section among the plurality of SOC sections;
identifying first OCV corresponding to the first SOC section by using the first parameter and the average OCV corresponding to all of the plurality of SOC sections; and
identifying the SOC of the battery by applying a first Kalman filter associated with a current integration method to the first OCV.

18. The method of claim 17, wherein identifying the SOC of the battery further includes:
classifying the plurality of SOC sections into the first SOC section and a second SOC section based on voltage characteristics of the battery; and
identifying the SOC of the battery by applying a second Kalman filter associated with a measurement equation to second OCV corresponding to the second SOC section.

19. The method of claim 18, wherein a voltage change rate of the first SOC section is lower than a voltage change rate of the second SOC section.

20. The method of claim 11, further comprising:
after identifying the SOC of the battery, obtaining another hysteresis parameter associated with another SOC, which is to be identified after the SOC of the battery is identified, by using the hysteresis parameter corresponding to each of the plurality of SOC sections and an SOC change amount of the battery corresponding to each of the plurality of SOC sections.
